(19) United States
(12) Patent Application Publication
(10) Pub. No.: US 2013/0001510 A1
(43) Pub. Date: Jan. 3, 2013

(54) OPTOELECTRONIC DEVICE HAVING CURRENT BLOCKING INSULATION LAYER FOR UNIFORM TEMPERATURE DISTRIBUTION AND METHOD OF FABRICATION

(75) Inventors: CHEN-FU CHU, Hsinchu City (TW); FENG-HSU FAN, Taoyuan County (TW)

(73) Assignee: SEMILEDS OPTOELECTRONICS CO., LTD., Chu-Nan (TW)

(21) Appl. No.: 13/535,794

(22) Filed: Jun. 28, 2012

Related U.S. Application Data
(60) Provisional application No. 61/502,436, filed on Jun. 29, 2011.

(51) Int. Cl. H01L 33/14; H01L 33/06

(52) U.S. Cl. 257/13; 438/29; 257/E33.008; 257/E33.011

(57) ABSTRACT

An optoelectronic device includes a conductive base, a reflective conductive layer on the conductive base, a first semiconductor layer on the conductive layer configured as a first confinement layer, an active layer on the first semiconductor layer configured to emit electromagnetic radiation, a second semiconductor layer on the active layer configured as a second confinement layer, an electrode on the second semiconductor layer, and a current blocking structure on the reflective conductive layer comprising a thin transparent insulation layer aligned with the electrode configured to block current flow from the electrode, to dissipate heat generated at an interface between the first semiconductor layer and the reflective conductive layer, and to transmit electromagnetic radiation reflected from the reflective conductive layer,

### CROSS REFERENCE TO RELATED APPLICATIONS

This application claims priority from provisional application Ser. No. 61/502,436 filed Jun. 29, 2011, which is incorporated herein by reference.

### BACKGROUND

This disclosure relates generally to optoelectronic devices and to methods for fabricating optoelectronic devices.

In an optoelectronic device, such as a light emitting diode (LED) device, in order to achieve optimal performance, it is important to have a uniform current distribution. For example, a uniform current distribution over the quantum well of a light emitting diode (LED) device provides a high lumens output and less heat generation. In order to achieve a uniform current distribution, optoelectronic devices are constructed with current blocking structures. For example, the upper electrode of a multi layer quantum well structure can be aligned with a current blocking layer for blocking a current path from the electrode though a semiconductor layer of the structure. U.S. Pat. Nos. 6,420,732; 7,795,623 and 7,759,670 disclose various current blocking structures for light emitting diode (LED) devices. These current blocking structures can include layers of reduced conductivity, as well as layers configured to form ohmic contacts or areas of high contact resistance.

One shortcoming of these prior art current blocking structures is that they adversely affect the heat distribution and temperature of the light emitting diode (LED) device. A uniform and symmetrical heat distribution is preferred for a reliable, high performance light emitting diode (LED) device. In addition, the output of light emitting diode (LED) devices, along with efficiency and life expectancy, decays exponentially with higher temperatures, such than lower temperatures are preferred. The present disclosure is directed to an optoelectronic device having a current blocking structure that provides complete current blocking and efficient heat distribution characteristics for providing low operating temperatures. In addition, the current blocking structure can be formed of a transparent material formed on a high reflectivity conductive layer to provide efficient light reflection from an active layer of the device.

### BRIEF DESCRIPTION OF THE DRAWINGS

Exemplary embodiments are illustrated in the referenced figures of the drawings. It is intended that the embodiments and the figures disclosed herein are to be considered illustrative rather than limiting.

FIG. 1A is a schematic cross sectional view of a prior art optoelectronic device having a current blocking structure and non-uniform heat distribution;

FIG. 1B is a schematic cross sectional view showing current paths and light paths through the optoelectronic device of FIG. 1A;

FIG. 1C is a schematic thermal image showing heat distribution in the optoelectronic device of FIG. 1A;

FIG. 2A is a schematic cross sectional view of an optoelectronic device having a current blocking structure configured to provide a uniform heat distribution and low operating temperatures;

FIG. 2B is a schematic cross sectional view showing current paths and light paths through the optoelectronic device of FIG. 2A;

FIG. 2C is a schematic thermal image showing uniform heat distribution in the optoelectronic device of FIG. 2A; and

FIG. 3 is a schematic cross sectional view of a current blocking structure in the optoelectronic device of FIG. 2A having a transparent, thermally conductive insulation layer in combination with a highly reflective conductive layer.

### DETAILED DESCRIPTION

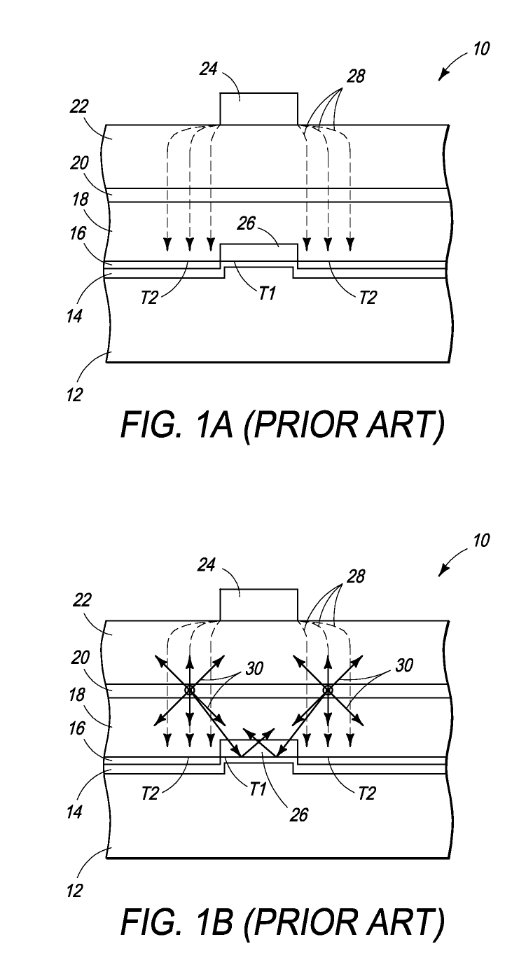

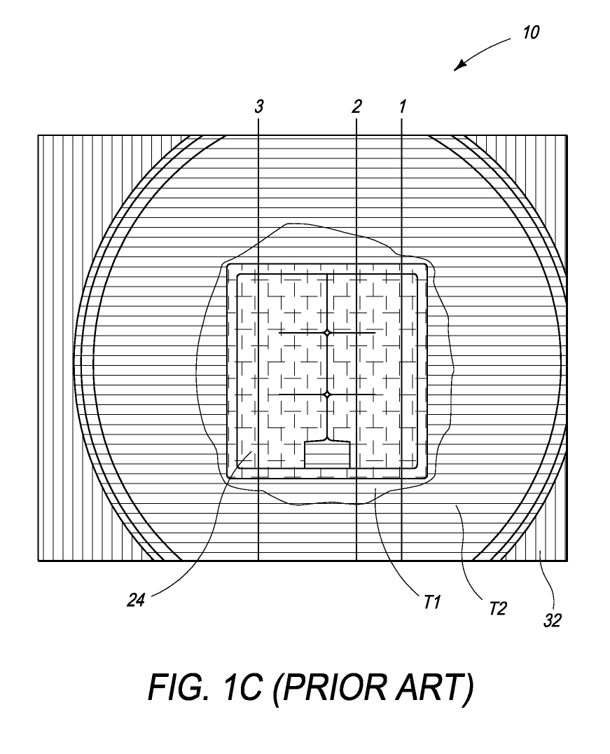

Referring to FIG. 1A, a prior art optoelectronic device 10 includes a conductive base 12, a first conductive layer 14, a second conductive layer 16, a first semiconductor layer 18, an active layer 20, a second semiconductor layer 22 and an electrode 24 on the second semiconductor layer 22. The optoelectronic device 10 also includes a current blocking structure 26, which comprises a first high resistance/heat generation region T1 on the first conductive layer 14 located subjacent to the electrode 24.

As indicated by the current paths 28 in FIG. 1A, the current blocking structure 26 blocks the direct current paths from the electrode 24 through the semiconductor layers 18, 22. In addition, a second high resistance/heat generation region T2 is located at the interface between the first conductive layer 14 and the first semiconductor layer 18. The temperature of the first high resistance/heat generation region T1 is larger than the temperature of the second high resistance/heat generation region T2 due to high resistance during current driving. Due to the different temperatures in the regions T1 and T2 heat distribution in the optoelectronic device 10 is non-uniform.

As shown in FIG. 1B, light travels in all directions 30 from the active layer 20 of the optoelectronic device 10. In addition, the first high resistance/heat generation region T1 has a low reflectivity, and the second high resistance/heat generation region T2 has a high reflectivity. As shown in FIG. 1C, the optoelectronic device 10 has a non-uniform heat distribution with the first high resistance/heat generation region T1 having a yellow thermal image, with the second high resistance/heat generation region T2 having a blue thermal image, and with the outer peripheral regions having a red thermal image.

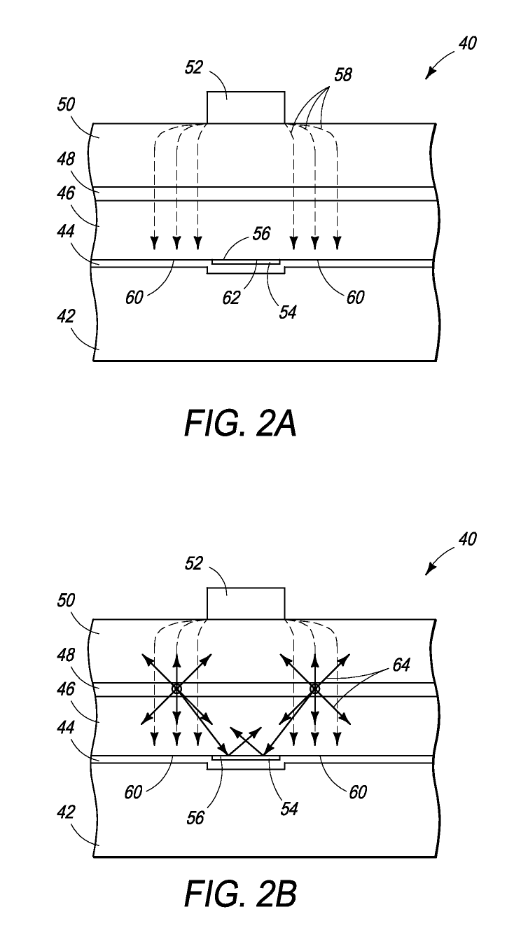

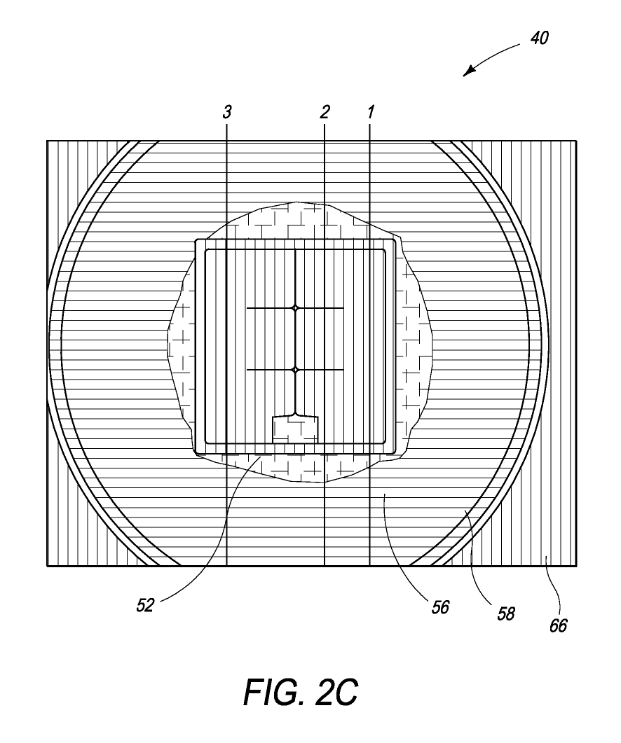

Referring to FIG. 2A, an optoelectronic device 40 includes a conductive base 42, a conductive layer 44, a first semiconductor layer 46, an active layer 48 configured to emit electromagnetic radiation, a second semiconductor layer 50 and an electrode 52 on the second semiconductor layer 50. The optoelectronic device 40 comprises a vertical light emitting diode (VLED) device. This type of vertical light emitting diode (VLED) die is further described in U.S. Pat. Nos. 7,195,944 and 7,615,789, both of which are incorporated herein by reference.

Still referring to FIG. 2A, the first semiconductor layer 46 can be configured as a p-type confinement layer 20 and can comprise p-GaN, p-AlGaN, p-InGaN, p-AlInGaN, p-AlInN or p-AlN. The second semiconductor layer 50 can be configured as an n-type confinement layer and can comprise n-GaN, n-AlGaN, n-InGaN, n-AlInGaN, AlInN or n-AlN. The active layer 48 can be configured as a multiple quantum well (MQW) layer and can comprise one or more quantum wells comprising one or more layers of InGaN/GaN, AlGaInN, AlGaN, AlInN and AlN. In addition, the active layer 48 can be configured to emit electromagnetic radiation from the visible spectral region (e.g., 400-770 nm), the violet-indigo spectral region (e.g., 400-450 nm), the blue spectral region (e.g., 450-490 nm), the green spectral region (e.g., 490-560 nm), the yellow spectral region (e.g., 560-590 nm), the orange spectral region (e.g., 590-635 nm) or the red spectral region (e.g., 635-700 nm). The electrode 52 can be configured as an n-electrode and can comprise conductive materials including Ti, Al, Ni, Pt, Ag and Au.

Still referring to FIG. 2A, the optoelectronic device 40 also includes a current blocking structure 54 comprising a thin, transparent insulation layer 56 formed on the conductive layer 44 located subjacent to and in alignment with the electrode 52. In addition, the peripheral shape of the transparent insulation layer 56 can substantially match the peripheral shape of the electrode 52. As indicated by the current paths 58 in FIG. 2A, the insulation layer 56 completely blocks all current flow from the electrode 52 directly through the semiconductor layers 46, 50. In addition, the interface 60 between the conductive layer 44 and the first semiconductor layer 46 provides interface resistance and a heat generation region. Further, the interface 62 between the insulation layer 56 and the first semiconductor layer 46 provides an infinite resistance and forms a no heat generation region.

Still referring to FIG. 2A, the insulation layer 56 can comprise a thin layer of a transparent insulating material configured to provide complete electrical current blocking but with thermal conducting properties to provide high thermal conductivity. Suitable materials for the insulation layer include SiO₂, Si₃N₄, Al₂O₃ and AlN. By way of example, AlN is a preferred material as it provides complete current blocking along with high thermal conductivity properties. As with the prior art device 10, in the optoelectronic device 40, heat is generated at the interface 60 between the conductive layer 44 and the first semiconductor layer 46. However, this heat is dissipated efficiently through the insulation layer 56 and the conductive layer 44 to the conductive base 42. In addition, the temperature and heat distribution are uniform throughout the device 40 due to the thermal conductivity properties of both the conductive layer 44 and the insulation layer 56. Further, the conductive layer 44 preferably has high reflective properties that work in combination with the light transparent properties of the insulation layer 56 to improve light reflection transmitted through the insulation layer 56 by reflection from the conductive layer 44. Suitable materials for the conductive layer 44 include Ag, Au, Al, Ni, Cr, Pt, Pd, Sn, Cu, ITO or multiple layers of the above metals or alloys thereof.

As shown in FIG. 2B, electromagnetic radiation, such as light, travels in all directions 64 from the active layer 48 of the optoelectronic device 40. In addition, the conductive layer 44 of the optoelectronic device 40 has a high reflectivity, and the transparent insulation layer 56 allows more light to reflect from the conductive layer 44 as this reflected light can pass through the transparent insulation layer 56. In this regard, please compare the reflectivity in FIG. 1B for the optoelectronic device 10 to the reflectivity in FIG. 2B for the optoelectronic device 40. Further, as shown in FIG. 2C, the optoelectronic device 40 has a uniform heat distribution and a good temperature uniformity, which is evenly distributed but without much variation from red near the electrode 52 to yellow along the periphery of the electrode 52, to blue in the current path 58, and back to red in the peripheral areas 66.

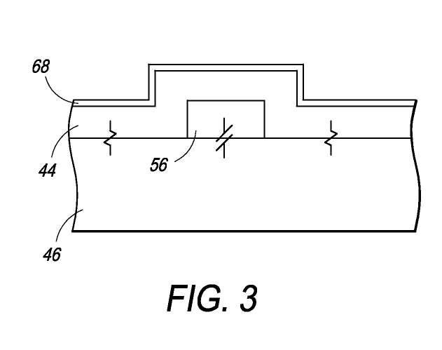

The optoelectronic device 40 provides the following advantages over the prior art optoelectronic device 10. (1) Uniform heat distribution, which provides a uniform temperature distribution. (2) The conductive layer 44 has good heat conductivity and forms a conductive reflector. (3) A conductive mirror 68 (FIG. 3) can optionally be formed on the transparent insulation layer 56 to provide additional reflectivity to reflect additional light through the transparent insulation layer 56. (4) The conductive mirror 68 (FIG. 3) on the transparent insulation layer 56 can extend the mirror size to reflect more light for high output power applications. (5) Good reliability can be obtained even with potential defects in the semiconductor layers 46, 50 covering the transparent insulation layer 56 especially under high current driving conditions.

Referring to FIG. 3, a method for fabricating the optoelectronic device 40 (FIG. 2A) with the conductive layer 44 and the insulation layer 56 is illustrated. As shown in FIG. 3, the insulation layer 56 can be deposited on the first semiconductor layer 46 using a suitable deposition process such as CVD, MOCVD, PECVD, ALD or PVD. A thickness of the insulation layer 56 can be from 1 Å to 1000 Å with about 100 Å being preferred. In addition, the insulation layer 56 can be aligned with the electrode 52 (FIG. 2B) and can have a peripheral shape (e.g., square, rectangular, round polygonal), which substantially matches the peripheral shape of the electrode 52.

As also shown in FIG. 3, the conductive layer 44 can be deposited on the first semiconductor layer 46 and on the insulation layer 56 using a suitable deposition process such as electro chemical deposition, electroless chemical deposition, CVD, MOCVD, PECVD, ALD or PVD. A thickness of the conductive layer 44 can be from 1000 Å0 to 10000 Å. In addition, the conductive layer 44 can optionally include a mirror layer 68 configured to provide high reflectivity within the wavelength range for the electromagnetic radiation emitted by the active layer 48. Under current driving conditions, a contact resistance R is formed between the interface of the conductive layer 44 and the first semiconductor layer 46. This contact resistance R is also a heat generator during current driving conditions. However, this heat can be dissipated efficiently due to the conductive layer 44 being formed of a metal having good thermal conductivity. As also shown in FIG. 3, the contact resistance R between the insulation layer 56 and the first semiconductor layer 46 is infinite, such than no heat is generated at the interface of the insulation layer 56 and the first semiconductor layer 46. In addition, uniform current spreading throughout the optoelectronic device 40 can be provided.

Thus the disclosure describes an improved optoelectronic device and method of fabrication. While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. An optoelectronic device comprising:
a conductive base;
a reflective conductive layer on the conductive base;
a first semiconductor layer on the reflective conductive layer configured as a first confinement layer;
an active layer on the first semiconductor layer configured to emit electromagnetic radiation;
a second semiconductor layer on the active layer configured as a second confinement layer;
an electrode on the second semiconductor layer; and
a transparent insulation layer on the reflective conductive layer aligned with the electrode configured to block current flow from the electrode, to dissipate heat and to transmit electromagnetic radiation reflected from the reflective conductive layer.

2. The optoelectronic device of claim 1 wherein the electrode has a first peripheral outline and the transparent insulation layer has a second peripheral outline substantially matching the first peripheral outline.

3. The optoelectronic device of claim 1 wherein the transparent insulation layer comprises a material selected from the group consisting of SiO₂, Si₃N₄, Al₂O₃ and AlN.

4. The optoelectronic device of claim 1 wherein the transparent insulation layer has a thickness of from 1 Å to 1000 Å.

5. The optoelectronic device of claim 1 wherein the transparent insulation layer has a thickness of 100 Å.

6. The optoelectronic device of claim 1 wherein the reflective conductive layer comprises a material selected from the group consisting of Ag, Au, Al, Ni, Cr, Pt, Pd, Sn, Cu, ITO and alloys thereof.

7. The optoelectronic device of claim 1 further comprising a mirror layer on the reflective conductive layer configured to reflect the electromagnetic radiation.

8. The optoelectronic device of claim 1 wherein the first semiconductor layer comprises a p-type confinement layer, the active layer comprises a multiple quantum well (MQW) layer and the second semiconductor layer comprises an n-type confinement layer.

9. The optoelectronic device of claim 1 wherein the optoelectronic device comprises a vertical light emitting diode (VLED).

10. An optoelectronic device comprising:
a conductive base;
a reflective conductive layer on the conductive base;
a first semiconductor layer on the conductive layer configured as a first confinement layer having a first interface with the reflective conductive layer configured to generate heat during operation of the electronic device;
an active layer on the first semiconductor layer configured to emit electromagnetic radiation;
a second semiconductor layer on the active layer configured as a second confinement layer;
an electrode on the second semiconductor layer having a first peripheral outline; and
a current blocking structure comprising a transparent insulation layer on the conductive layer aligned with the electrode configured to block current flow from the electrode, to dissipate the heat generated at the first interface and to transmit electromagnetic radiation reflected from the reflective conductive layer, the transparent insulation layer having a second peripheral outline substantially matching the first peripheral outline.

11. The optoelectronic device of claim 10 wherein the transparent insulation layer comprises a material selected from the group consisting of SiO₂, Si₃N₄, Al₂O₃ and AlN, and the reflective conductive layer comprises a material selected from the group consisting of Ag, Au, Al, Ni, Cr, Pt, Pd, Sn, Cu, ITO and alloys thereof.

12. The optoelectronic device of claim 10 wherein the transparent insulation layer has a thickness of from 1 Å to 1000 Å.

13. The optoelectronic device of claim 10 wherein the transparent insulation layer has a thickness of 100 Å.

14. The optoelectronic device of claim 10 wherein the first semiconductor layer comprises a p-type confinement layer, the active layer comprises a multiple quantum well (MQW) layer and the second semiconductor layer comprises an n-type confinement layer.

15. The optoelectronic device of claim 10 wherein the optoelectronic device comprises a vertical light emitting diode (VLED).

16. A method for fabricating an optoelectronic device comprising:
forming a conductive base;
forming a reflective conductive layer on the conductive base;
forming a current blocking structure comprising a transparent insulation layer on the reflective conductive layer having thermal conductivity properties;
forming a first semiconductor layer on the reflective conductive layer and on the insulation layer configured as a first confinement layer;
forming an active layer on the first semiconductor layer configured to emit electromagnetic radiation;
forming a second semiconductor layer on the active layer configured as a second confinement layer; and
forming an electrode on the second semiconductor layer aligned with the transparent insulation layer.

17. The method of claim 16 wherein the transparent insulation layer comprises a material selected from the group consisting of SiO₂, Si₃N₄, Al₂O₃ and AlN.

18. The method of claim 16 wherein the transparent insulation layer has a thickness of from 1 Å to 1000 Å.

19. The method of claim 16 wherein the reflective conductive layer comprises a material selected from the group consisting of Ag, Au, Al, Ni, Cr, Pt, Pd, Sn, Cu, ITO and alloys thereof.

20. The method of claim 16 wherein the first semiconductor layer comprises a p-type confinement layer, the active layer comprises a multiple quantum well (MQW) layer and the second semiconductor layer comprises an n-type confinement layer.
